(19) United States
(12) Patent Application Publication
(10) Pub. No.: US 2014/0218848 A1
(43) Pub. Date: Aug. 7, 2014

(54) ELECTRONICS LIGHT COVER AND METHOD OF USE

(71) Applicant: Matthew Cannon, Sparks, NV (US)

(72) Inventor: Matthew Cannon, Sparks, NV (US)

(21) Appl. No.: 14/166,828

(22) Filed: Jan. 28, 2014

Related U.S. Application Data
(60) Provisional application No. 61/757,551, filed on Jan. 28, 2013.

(51) Int. Cl. F21V 1/00; H05K 7/00

(52) U.S. Cl. CPC F21V 1/00; H05K 7/00
USPC 361/679.01; 29/428

(57) ABSTRACT

One possible embodiment of the invention could be a cover in combination with an electronic device and a method of operating same, the combination comprising the electronic device having at least one illumination source; the cover being made of a sheet of opaque flexible material, the cover having two positions, a first position that blocks a transmission of a light from the at least one illumination source from passing onto the electronic device's external environment and a second open position that allows the transmission of the light from the at least one illumination source to pass onto the electronic device's external environment; wherein the cover is attached to the electronic device in a manner that places the cover proximate to the at least one illumination source.

### STATEMENT REGARDING FEDERALLY SPONSORED RESEARCH OR DEVELOPMENT

Not Applicable

### REFERENCE TO A “MICROFICHE APPENDIX”

Not Applicable.

### FIELD OF THE INVENTION

The present invention relates to those covers that may be used to control the light transmission of illumination sources of electronic devices. In particular to those covers, which may either block the light transmissions or allow the passage of the light transmissions to the electronic devices external environment.

### BACKGROUND

There appears to be a growing awareness in the medical field about increasing amount of light illumination/pollution within the home and its possible adverse health issues that it may pose for the home occupants. For instance, blue light, which is found within the spectrum of light generally emitted by LEDs (i.e., Light Emitting Diode) as used in electronic devices (e.g., such as home entertainment systems, digital clocks, televisions, PC computers, laptops, smart phones and the like) to communicate the status or condition of those electronics to their operators or users, appears to be connected with an inhibition of human melanin production. Melanin, which generally allows the tanning of skin, is also the substance that gives eyes their color. In this manner, melanin further protects the macula of the eye by trapping light rays so they don't reach the macula and cause damage. People with fair skin and blue or light-colored eyes may be particularly susceptible to blue light-based macular damage because they have less melanin in their irises. In addition, Seasonal Affective Disorder (SAD) based on a melatonin mechanism may also be affected by such blue light emissions.

Currently, medical science is further examining how the increase of light at night (i.e., LAN) pollution during the 20th century coincides with increasing rates of obesity and metabolic disorders throughout the world. Initial laboratory studies appear to indicate that LAN exposure to may alter circadian organization and otherwise affect metabolic parameters. One possible aspect of this situation could be found in modern day bedrooms that have become a repository of many continuously energized electrical devices that feature LED and the like light sources. Such LAN emissions in a bedroom may interfere with nocturnal sleeping and other biological patterns of the bedroom occupants.

What could be needed therefore is a cover that could affix to an external surface of an electronic device to reversibly block light emissions of electronic device's light emission source(s) to an environment external to the electronic device during nocturnal or sleeping periods. The cover could overlay the light emission source/block transmission of the light until the operator wanted to check the operational condition/status of the electronic device as provided by the light emission source. The operator could then actuate or otherwise move such a cover in a manner that generally allows transmission of the illumination through to the external environment to permit the operator to ascertain the operational status of the electronic device.

### SUMMARY OF ONE EMBODIMENT OF THE INVENTION

### Advantages of One or More Embodiments of the Present Invention

The various embodiments of the present invention may, but do not necessarily, achieve one or more of the following advantages:

to provide a cover that attaches to an electronic device to reversibly block the light transmissions by such electronic devices until the operator of the electronic devices wishes to ascertain the operating status or condition of the electronic device;

the ability to manipulate a cover as attached to an electronic device to control light transmission of light source from the electronic device to generally emanate out to the environment external to the electrical device;

to provide a removable cover for an electronic device that can significantly reduce the amount of blue light emissions from the electronic device from reaching the outside environment;

to provide a removable cover for an electronic device that can control or otherwise reduced the amount of blue light emissions from the electronic device from passing to a room where people are sleeping.

the ability to use a cover to control the amount of nocturnal light emissions emanating from an energized electronic device into an bedroom environment where the electronic device is located; and

to provide a cover that can attach to an electronic device without damaging the external surface of the electronic device, the cover being operated to control the transmission of light by one or more illumination or light sources of the electronic devices to the electronic devices' eternal environments.

These and other advantages may be realized by reference to the remaining portions of the specification, drawings, claims, and abstract.

### Brief Description of One Embodiment of the Present Invention

One possible embodiment of the invention could be a method for operating a cover for an electronic device, comprising of the following steps, providing the electronic device, the electronic device having at least one illumination source; providing the cover, the cover having two operating positions, a first closed position that blocks a transmission of light from the illumination source to the electronic device's external environment and a second open position that allows the transmission of light from the illumination source; attaching the cover to the electronic device proximate to the at least one illumination source; placing the cover being in the first closed position; and blocking the transmission of light from the at least one illumination source.

Another possible embodiment of the invention could be a cover in combination with an electronic device, the combination comprising: the electronic device having at least one illumination source; the cover being made of a sheet of opaque flexible material, the cover having two positions, a first position that blocks a transmission of a light from the at least one illumination source and a second open position that allows the transmission of the light from the at least one illumination source; wherein the cover is attached to the electronic device in a manner that places the cover proximate to the at least one illumination source.

Still yet another possible embodiment could be a cover in combination with an electronic device, the combination comprising the electronic device having at least one illumination source; the cover having a low adhesion adhesive coating, a flap and a base sheet, the base sheet having a first and a second side and further being comprised of a material that is at least translucent, the low-adhesion adhesive coating being applied to the second side, the flap being comprised of an opaque material, the flap further connects to the base sheet to provide the cover with two operating positions, a first position that blocks a transmission of a light from the at least one illumination source and a second open position that allows the transmission of the light from the illumination source; wherein the base sheet is removably attached by the low-adhesion adhesive coating to the electronic device to place the cover proximate to the at least one illumination source.

The above description sets forth, rather broadly, a summary of one embodiment of the present invention so that the detailed description that follows may be better understood and contributions of the present invention to the art may be better appreciated. Some of the embodiments of the present invention may not include all of the features or characteristics listed in the above summary. There are, of course, additional features of the invention that will be described below and will form the subject matter of claims. In this respect, before explaining at least one preferred embodiment of the invention in detail, it is to be understood that the invention is not limited in its application to the details of the construction and to the arrangement of the components set forth in the following description or as illustrated in the drawings. The invention is capable of other embodiments and of being practiced and carried out in various ways. Also, it is to be understood that the phraseology and terminology employed herein are for the purpose of description and should not be regarded as limiting.

### BRIEF DESCRIPTION OF THE DRAWINGS

FIG. 1 is substantially a perspective view of one embodiment of the present invention respectively.

FIGS. 1A and 1B are substantially perspective views of one embodiment of the present invention respectively showing a first closed position and a second open position.

FIG. 2 is substantially a perspective view of another embodiment of the present invention respectively.

FIG. 2A is substantially perspective views of another embodiment of the present invention respectively showing a first closed position.

FIGS. 2B is substantially perspective views of another embodiment of the present invention respectively showing a first closed position and a second open position.

FIG. 3 is substantially a perspective view of yet another embodiment of the present invention.

FIG. 3A is substantially a cutaway perspective view of yet another embodiment of the present invention respectively showing a first closed position.

FIG. 3B is substantially a cutaway perspective view of yet another embodiment of the present invention respectively showing a second open position.

FIG. 4 is substantially a cutaway perspective view of still yet another embodiment of the present invention.

FIG. 4A is substantially a cutaway perspective views of still yet another embodiment of the present invention respectively showing a first closed position.

FIG. 4B is substantially a cutaway perspective view of still yet another embodiment of the present invention respectively showing a second open position.

FIG. 5 is substantially a flowchart schematic of one possible embodiment of operating the present invention.

### DESCRIPTION OF CERTAIN EMBODIMENTS OF THE PRESENT INVENTION

In the following detailed description of the preferred embodiments, reference is made to the accompanying drawings, which form a part of this application. The drawings show, by way of illustration, specific embodiments in which the invention may be practiced. It is to be understood that other embodiments may be utilized and structural changes may be made without departing from the scope of the present invention.

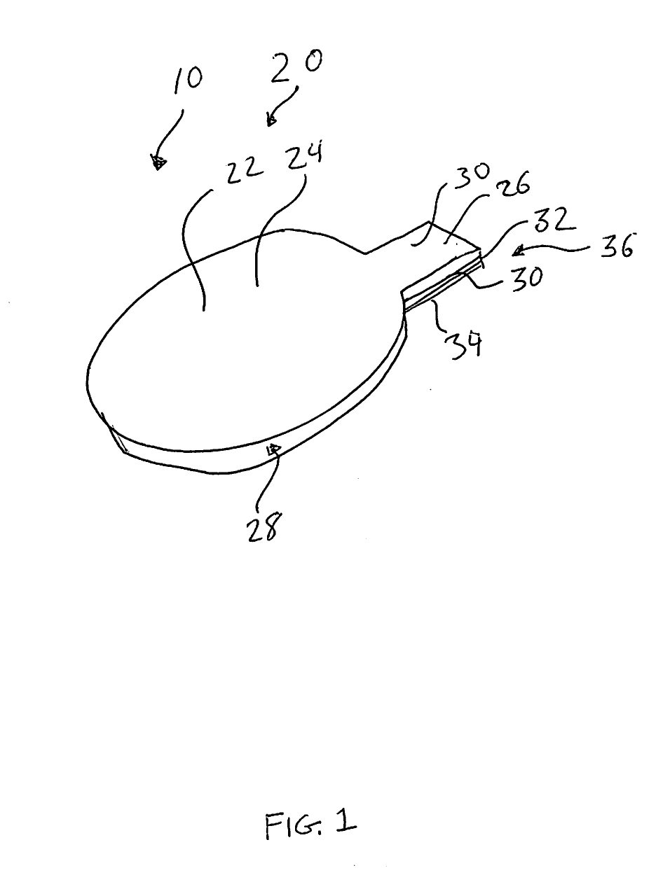

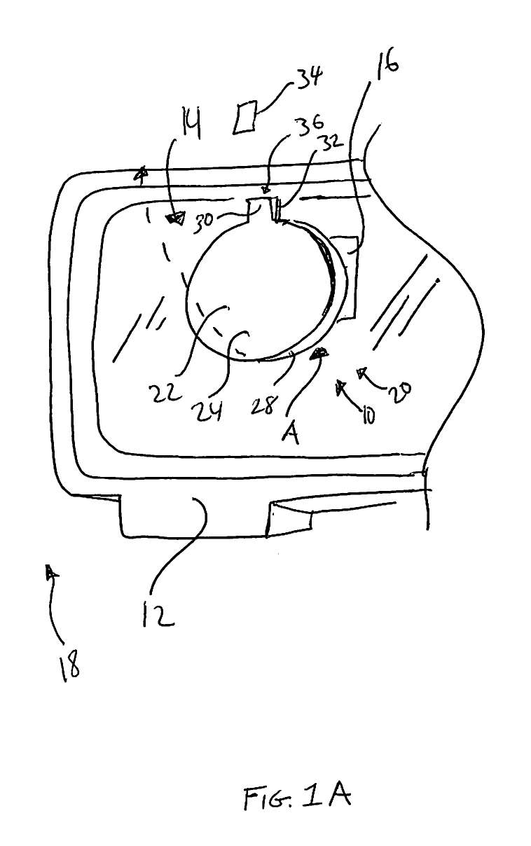

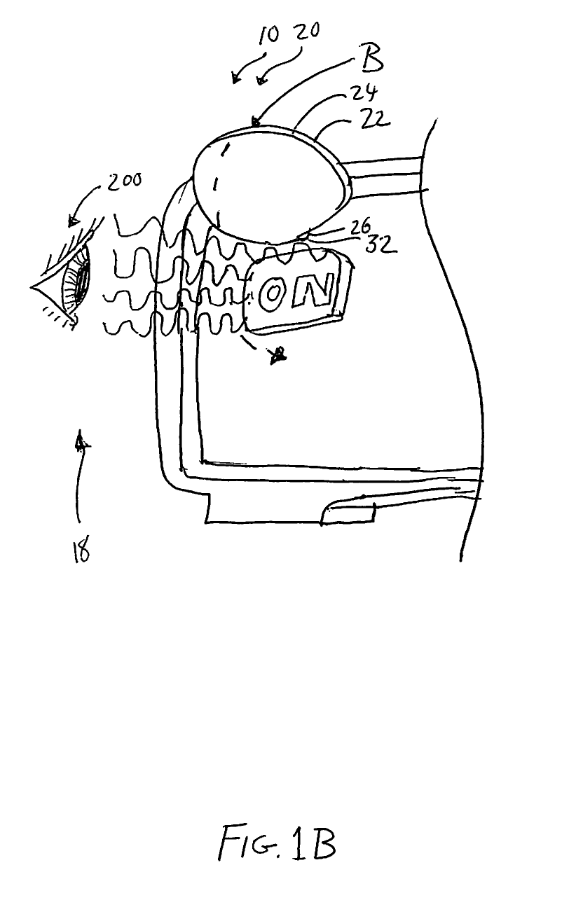

The present invention 10 could comprise of a cover 20 and a method or process 100 of its use in controlling the transmission of light from an illumination source of an electronic device to an external environment. As substantially shown in FIGS. 1, 1A, and 1B, one such embodiment for the cover 20 could be a flap 22 comprising of a sheet 24 of opaque, flexible material (e.g., a polymer film.) The sheet 24 could have circular dimension with a tab 26 projecting outward from an edge or circumference 28 of the sheet 24. The tab 26 could have two sides 30 with one side having a low adhesion adhesive coating 32 applied to it. A removable cover 34 in similar dimension to the tab 26 could be removably attached to the low adhesion adhesive coating 32 to substantially sandwich the low adhesion adhesive coating 32 between the tab 26 and the removable cover 34 to generally form a laminate 36.

In use, the cover 20 could be placed on an indicator panel or other portion of an exterior 14 of an electrical device 12 in a manner to allow the cover 20 to generally block such light transmission to the environment external 18 to the electronic device 12 (e.g., allowing the occupants of a bedroom better sleep at night when such electrical device[s] is [are] located in the bedroom; limiting exposure of electronic device's operators or users to potentially harmful blue light emissions; and the like.) The invention 10 could also allow an electronic device's operator or user 200 to manipulate the cover 20 (allowing passage of light) to see if the illumination source 16 is energized/transmitting light in a manner that denotes the operative condition/status of the electronic device 12.

The removable cover 34 could be first pulled off the laminate 36 to expose the low adhesion adhesive coating 32 to allow the cover 20 to be applied (e.g., removably) to the exterior 18 of the electronic device 12. The cover 20 (as attached by its tab 26) could be located proximate to at least an illumination source 16 of the electronic device 12 in a manner that generally allows the cover 20 to block transmission of light of the illumination source 16.

For example, if the electronic device's exterior surface 14 is horizontally oriented, then the tab 26 could be located upwards of the remaining portion of the cover 20 so that the force of gravity could pull down the remaining cover 20 over the illumination source 16 into a first resting or closed position A. In this manner, the operator 200 could grasp the edge 28 of the cover 20 generally opposite of the location of the tab 26 on the circumference 28 to lift up the remaining portion of the cover 20 up and away from the exterior 14 into a second open position B to allow the transmission of light from the illumination source 16 (if appropriately energized) to pass the cover 20 onto to the environment external to the electronic device 12. The operator 200 after observing any illumination (or lack thereof) from the illumination source 16 could then release the cover 20 to allow the cover 20 to go back into the first closed position A generally covering/blocking any illumination otherwise emanating from the illumination source 16.

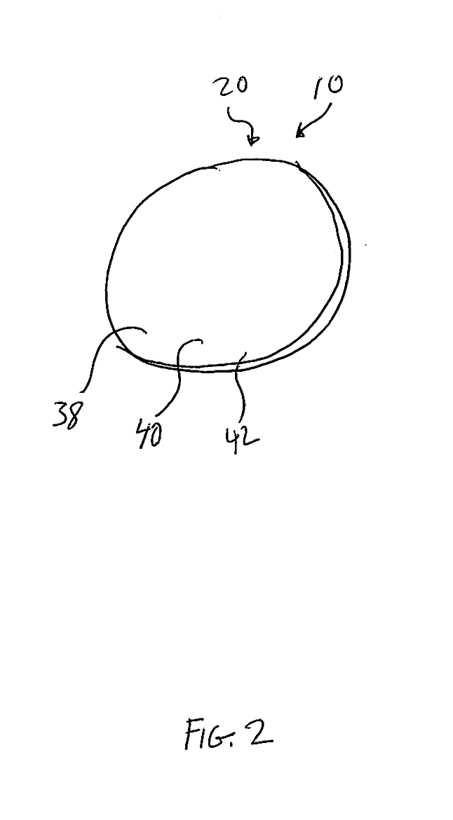

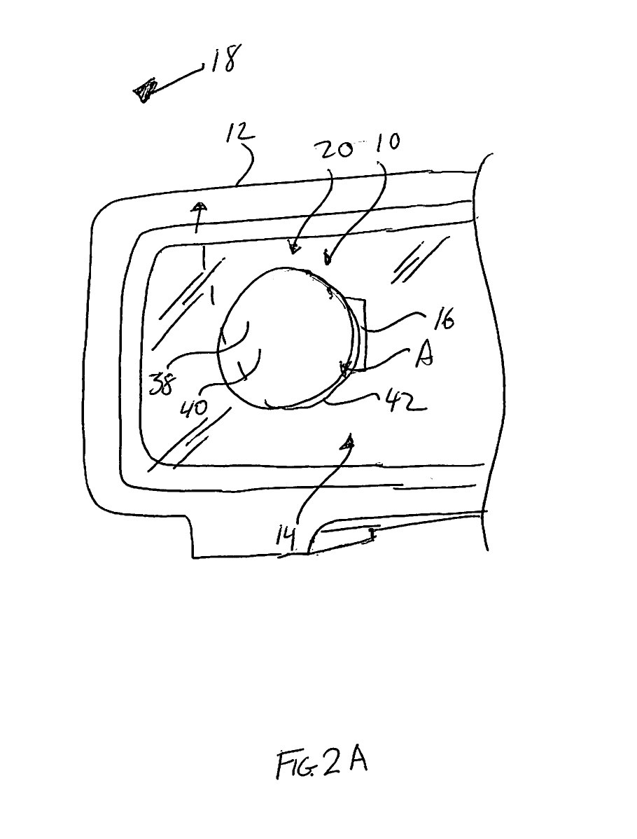

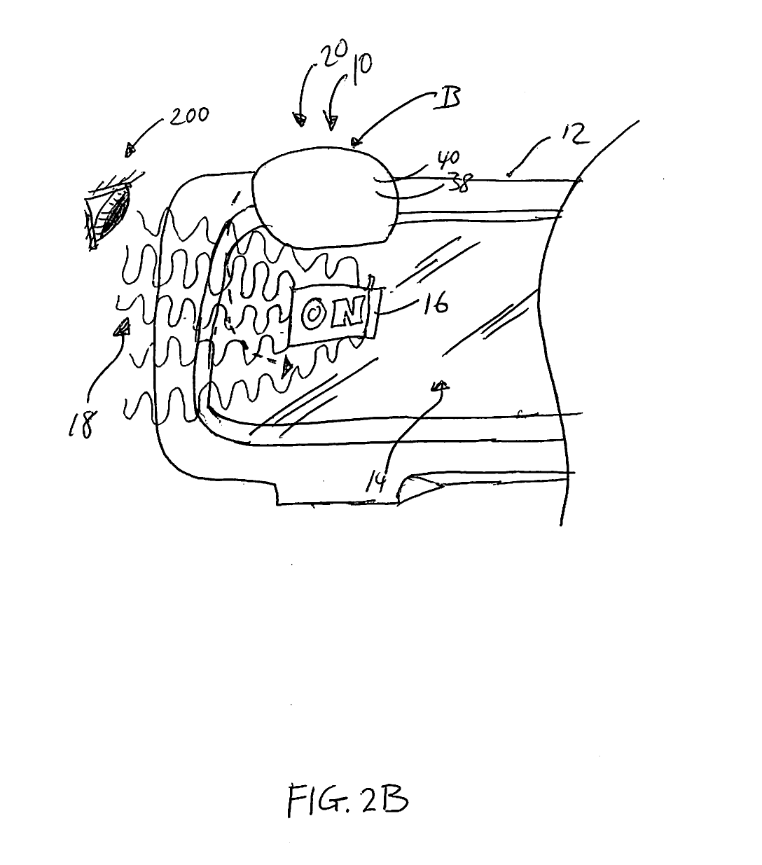

As substantially shown in FIGS. 2, 2A, and 2B, is another possible embodiment of the cover 20 as a flap 38 made from an opaque, low adhesion sheet 40 such as polyvinylchloride (PVC) static cling film. The sheet 40 could be made or cut to suitable dimensions (length, width, shape, etc.) to allow the flap 38 to be removably attached to (e.g., laid upon) an exterior 14 (e.g. instrumentation panel) of the electronic device 12. The flap 40 should be positioned over at least one electrical device's illumination source 16 to be able to control its light transmission to the external environment 18 when the illumination source 16 is energized. When the flap 38 is fully laid upon exterior 14, the flap 38 could be considered placed in a first closed position A. The operator 200 could the grasp an edge 42 of the flap 38 and peel a portion of the flap 38 into a second open position B that is generally distal from the electronic device 12 to allow an operator 200 to observe any illumination being emitted by an energized illumination source 16 of the electrical device 12 to the external environment 18. Once the operator has concluded its observations relating to the electrical device/illumination source, the flap 38 could be replaced in its first closed position A.

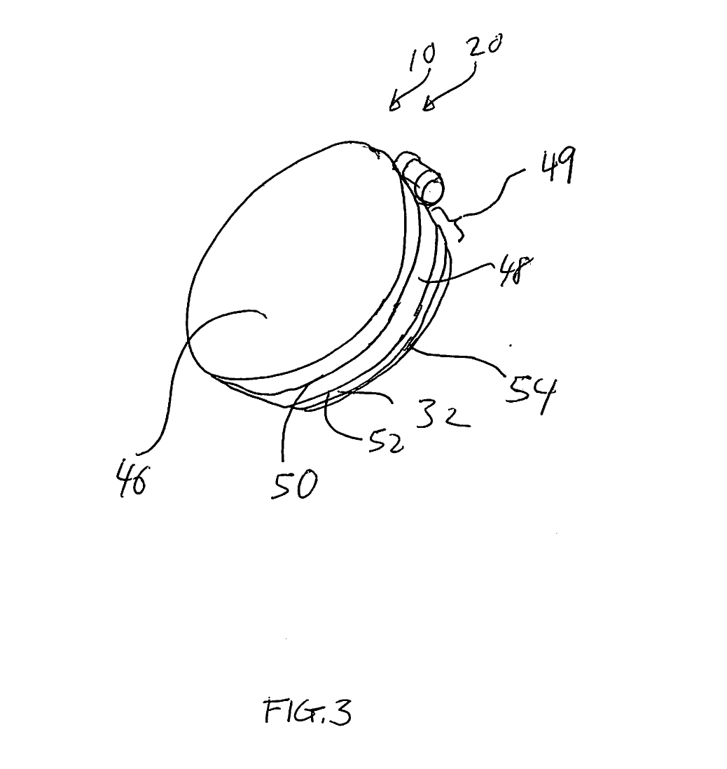

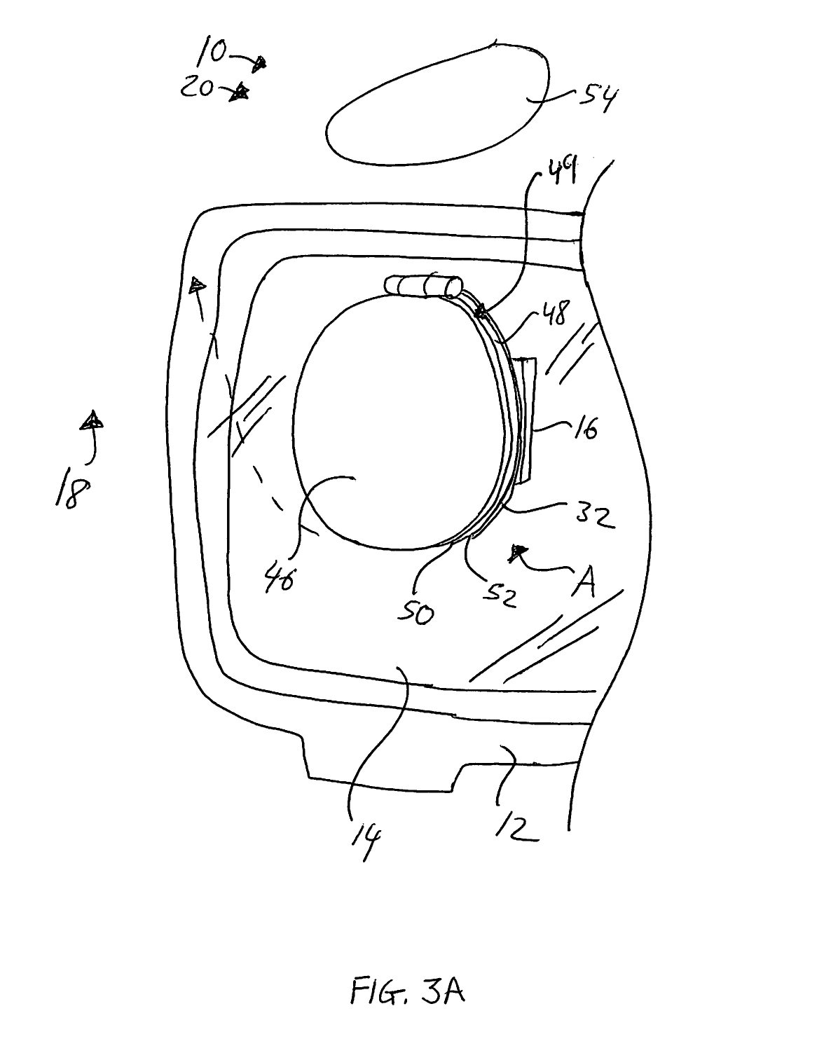

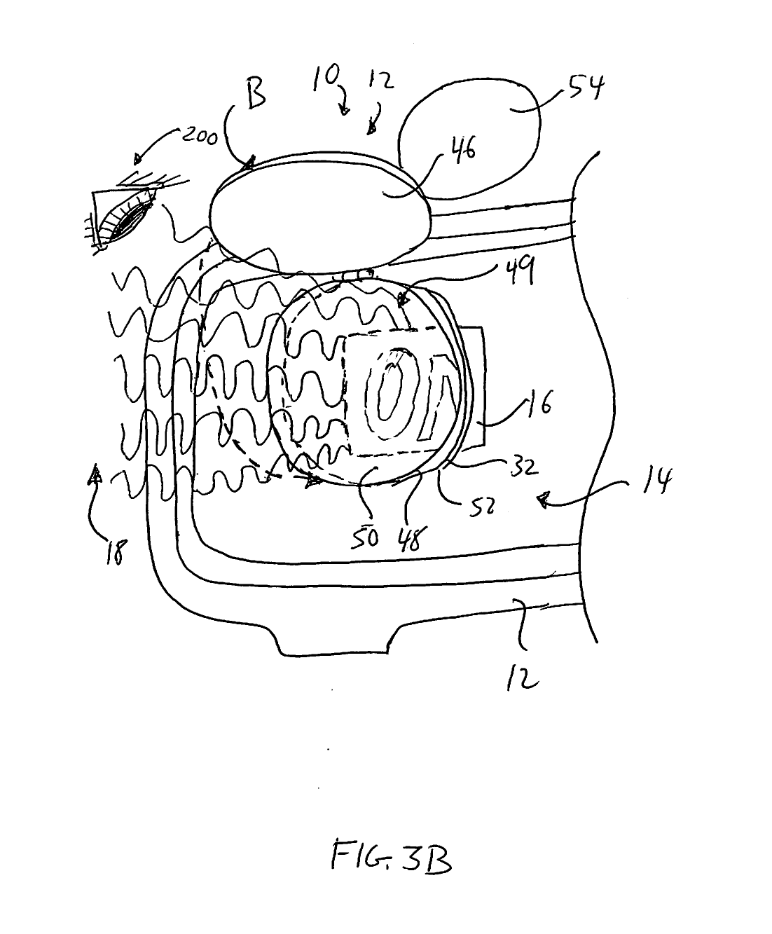

As substantially shown in FIGS. 3, 3A, and 3B, yet another possible embodiment of the cover 20 could comprise of a base sheet laminate 49 and a flap 46. The base sheet laminate 49 could be made a base sheet 48, a transparent (or at least translucent) low-adhesion adhesive coating 32, and a base sheet covering 54. The base sheet 48 could be made of a transparent (or at least translucent) material such as a clear polymer film having two sides, a first side 50 and a second side 52. The transparent low-adhesion adhesive coating 32 could be applied to the second side 52 to allow the base sheet covering 54 to be removably attached to the low-adhesion adhesive coating 32 between the base sheet covering 54 and the base sheet 48 to form the base sheet laminate 49.

The flap 46 could be made from suitable opaque material and be formed to have a shape generally matching that of the base sheet 48. The flap 46 could be hingedly connected to the first side 50 (e.g., by an edge) of the base sheet 48 to allow the flap 46 to removably cover the first side 50 when placed in a first closed position A and then be distal from the first side 50 when the flap 46 is placed in a second open position B.

When the base sheet covering 54 is removed from the remaining base sheet laminate 49, the exposed low adhesion adhesive coating 32 could affix (e.g., removably) the remaining cover 20 to the exterior 14 of the electronic device 12. The cover 20 could be located proximate to the electrical device illumination source 16 so that when the flap 46 is in the first open position A, the flap 46 blocks an illumination of an energized illumination source 16 through the cover 20. When the flap 46 is placed in a second open position B, the illumination could be transmitted through the cover 20 to the environment external 18 to the electronic device 12.

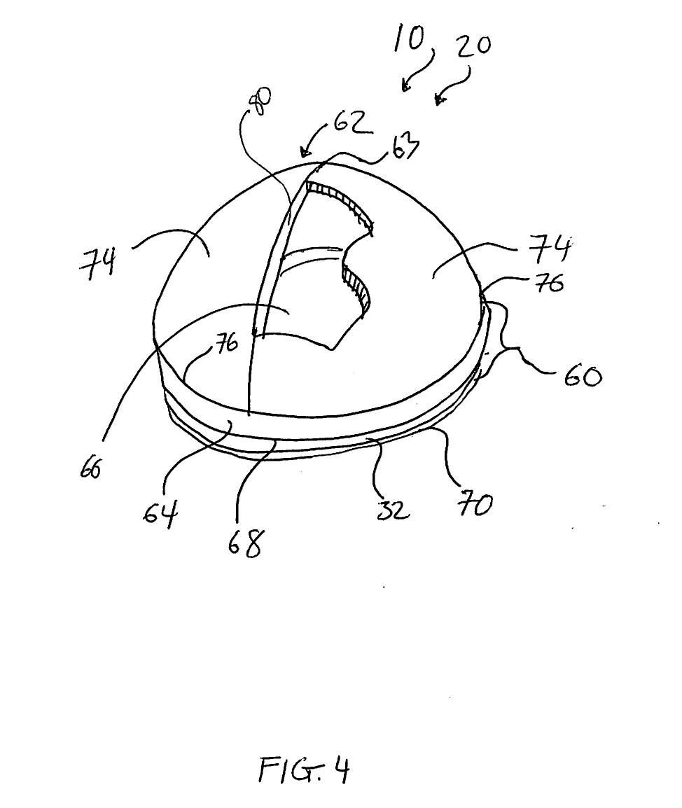

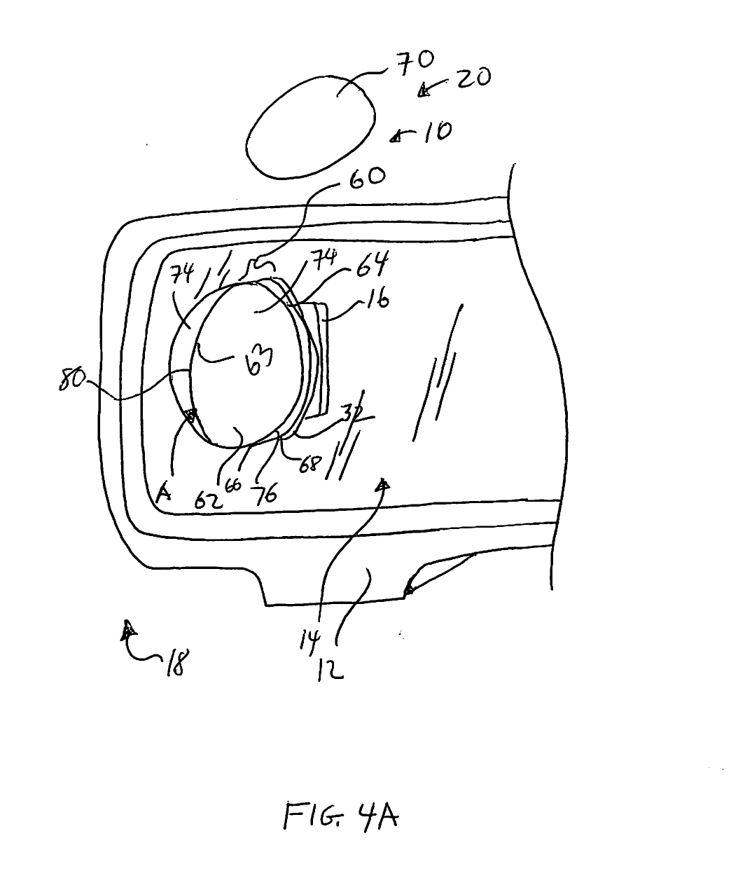

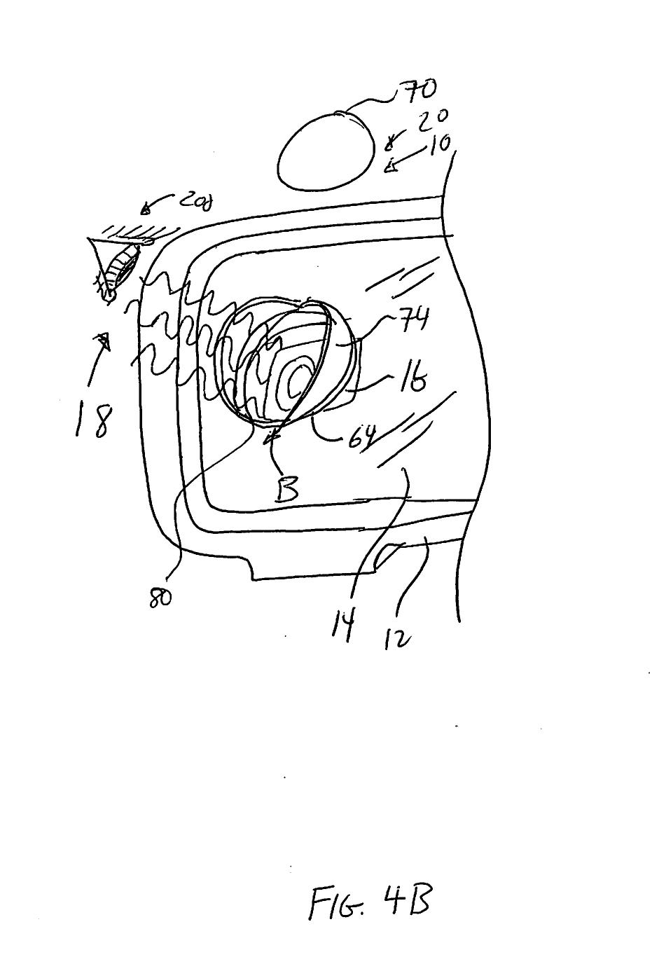

As substantially shown in FIGS. 4, 4A and 4B, still yet another possible embodiment of the cover 20 could be comprise a base sheet laminate 60 and a hemispherically-shaped flap 62. The base sheet laminate 60 could comprise of a base sheet 64 made of a transparent (or at least translucent) material such as a clear polymer film, the base sheet 64 further denoting a first side 66 and second side 68. The second side 68 could have a transparent (or at least translucent) low-adhesion adhesive coating 32 applied to it to allow the base sheet covering 70 to generally sandwich the low-adhesion adhesive coating 32 between the base sheet covering 70 and the base sheet 64 to generally complete a base sheet laminate 72.

The hemispherically-shaped flap 62 could be made of opaque, flexible material, the hemispherically-shaped flap 62 having a slit 63 running down the flap's middle 80 and further bisecting the hemispherically-shaped flap 62 flap into matching halves 74. The hemispherically-shaped flap 62 could be suitably attached by its flap edges 76 to the first side 66 of the base sheet 64.

In operation, the base sheet covering 70 could be removed from the remainder of the base sheet laminate 72 to expose low adhesion adhesive coating 32 that would then be used to attach the base sheet 64 to be removably attached to the exterior of the electronic device 12 proximate to the illumination source 16. In a first closed position A, the hemispherically-shaped flap 62 with its middle 80 closed generally prevents the transmission of a light, as created by an energized illumination source 16, though the cover 20 to an environment external 18 to the electronic device 12. If the hemispherically-shaped flap 62 is pulled apart by its halves 74 to open along the flap's middle 80, such as the operator placing its finger along the slit 63 to force open the middle 80, the hemispherically-shaped flap 62 can be seen as obtaining a second open position A wherein light of the energized illumination source 16 could pass through the low adhesion adhesive 32, base sheet 64 and through the opening 78 created by the forced apart middle/halves 74 of the hemispherically-shaped flap 62 to the environment external 18 to the electronic device 12.

Method

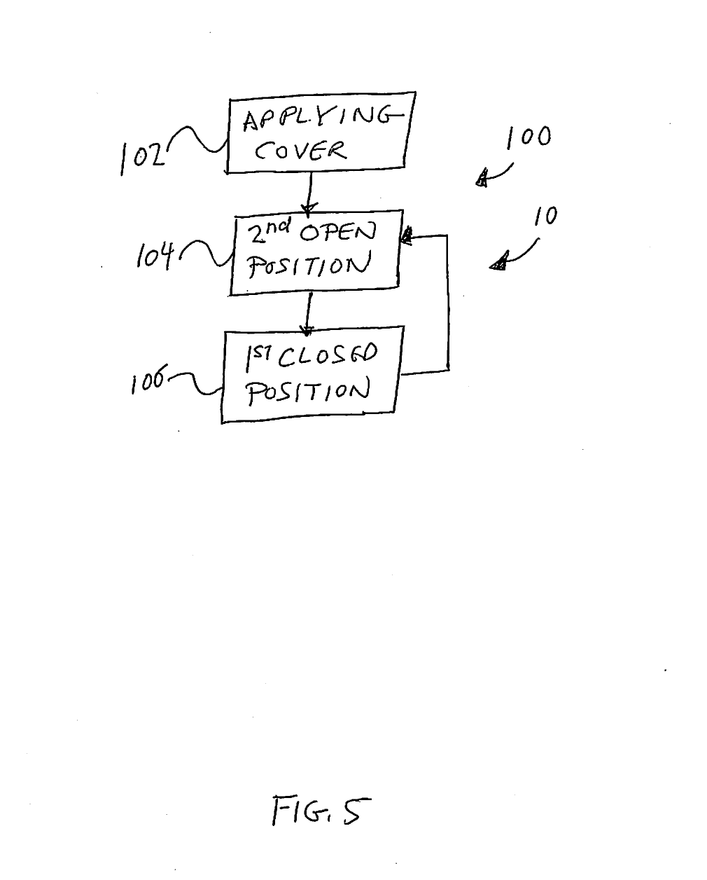

As substantially shown in FIG. 5, one possible method or process 100 for operating the cover could start with step 102, applying the cover to the electronic device. In the PVC static cling film base version of the cover, the film could be applied over the electronic device's exterior to cover an illumination source. In the low adhesion adhesive version of the cover, the base sheet cover could be removed from the cover to expose the low adhesion adhesive coating. The coating is then placed in contact with the electronic device's exterior to cover an illumination source. Generally, as so applied to the electronic device 12, the coverings 20 are initially placed in a first closed position. As this step is substantially completed, the process 100 could proceed to step 104, placing in the second position.

In step 104, placing in the second open position, the operator 200 could for the static cling film version of the invention 10 could grasp a side of the film and move a portion of the film distal to the exterior. For the low adhesion adhesive version of the cover, the operator 200 could grasp a side edge of the flap pivoting/moving the flap by an opposing edge to generally rotate the flap upwards and away from the exterior. For the semi-hemispherical version of the cover, the operator 200 could force apart the halves to create an opening in the middle of the flap to place the flap in the second position. Once the flap/film is in the second position light from an energized illumination source can pass through to the external environment to be observed by the operator 200. The second open position also allows the operator 200 to observe the illumination source to inform the operator 200 of various conditions/operational status of the electronic device. After this step is substantially completed, the process 100 can proceed to step 106, returning the cover back to the first closed position.

In step 106, returning the cover back to the first closed position, the operator 200 places the cover back into the first closed position, by releasing the halves; replacing the film on the exterior; putting the flap back over the base sheet; or the like step to generally prevent the light from an energized illumination source from passing through the cover to the environment external to the electronic device. The process can then return to step 104 as needed.

### Conclusion

Although the description above contains many specifications, these should not be construed as limiting the scope of the invention but as merely providing illustrations of some of the presently preferred embodiments of this invention. Thus, the scope of the invention should be determined by the appended claims and their legal equivalents rather than by the examples given.

As substantially described and generally shown in the present application, the invention could be a cover that attaches to an electronic device to control the light transmissions by such electronic devices to significantly reduce the amount of light emissions (e.g., blue light and nocturnal light emissions) that otherwise would reaching the electronic device's external environment until the operator 200 of the electronic device wishes to momentarily ascertain the operating status or condition of the electronic device.

What is claimed is:

1. A method for operating a cover for an electronic device, comprising of the following steps, but not necessarily in the order shown:
(A) providing the electronic device, the electronic device having at least one illumination source;
(B) providing the cover, the cover having two operating positions, a first closed position that blocks a transmission of light from the at least one illumination source from passing onto the electronic device's external environment and a second open position that allows the transmission of light from the at least one illumination source to pass onto the electronic device's external environment;
(C) attaching the cover to the electronic device proximate to the at least one illumination source;
(D) placing the cover being in the first closed position; and
(E) blocking a transmission of light from the at least one illumination source from passing onto the electronic device's external environment.

2. The method of claim 1 further comprising a step of moving the cover from the first closed position to the second open position.

3. The method of claim 2 wherein the step of moving the cover from the first closed position to a second open position further comprises a step of allowing the transmission of light from the at least one illumination source to pass onto the electronic device's external environment.

4. The method of claim 2 wherein the step of moving the cover from the first closed position to a second open position further comprises a step of moving the cover about a tab that is anchoring the cover to the electronic device.

5. The method of claim 2 wherein the step of moving the cover from the first closed position to a second open position further comprises a step of peeling back an edge of the cover to lift at least a portion of the cover up and away from the electronic device.

6. The method of claim 2 wherein the step of moving the cover from the first closed position to a second open position further comprises a step of moving an opaque flap that is hingedly connected to a base sheet that is at least translucent and attached to the electronic device.

7. The method of claim 2 wherein the step of moving the cover from the first closed position to a second open position further comprises a step of opening a slit of an hemispherically-shaped flap, the flap being attached to a base sheet that is at least translucent and is attached to the electronic device.

8. The method of claim 7 wherein the step of opening a slit further comprises a step of allowing the transmission of the light from the at least one illumination source to pass through the base sheet and pass through a low adhesion adhesive coating that attaches the base sheet to the electronic device.

9. A cover in combination with an electronic device, the combination comprising:
(A) the electronic device having at least one illumination source;
(B) the cover being made of a sheet of opaque flexible material, the cover having two positions, a first position that blocks a transmission of a light from the at least one illumination source from passing onto the electronic device's external environment and a second open position that allows the transmission of the light from the at least one illumination source to pass onto the electronic device's external environment;
wherein the cover is attached to the electronic device in a manner that places the cover proximate to the at least one illumination source.

10. The combination of claim 9 wherein the cover further comprises a flap with a projecting tab having two sides, one side having low adhesion adhesive coating.

11. The combination of claim 10 wherein the low adhesion adhesive coating anchors the cover to the electronic device.

12. The combination of claim 11 wherein the flap moves about the tab to move the cover between the first closed position and a second open position.

13. The combination of claim 9 wherein the opaque flexible material is a static cling film.

14. A cover in combination with an electronic device, the combination comprising:
(A) the electronic device having at least one illumination source, the at least one illumination source capable of communicating to an operator of the electronic device as to the status of the electronic device;
(B) the cover having a low adhesion adhesive coating, a flap and a base sheet, the base sheet having a first and a second side and further being comprised of a material that is at least translucent, the low-adhesion adhesive coating being applied to the second side, the flap being comprised of an opaque material, the flap further connects to the base sheet to provide the cover with two operating positions, a first closed position that blocks a transmission of a light from the at least one illumination source from passing onto the electronic device's external environment and a second open position that allows the transmission of the light from the illumination source to pass onto the electronic device's external environment;
wherein the base sheet is removably attached by the low-adhesion adhesive coating to the electronic device to place the cover proximate to the at least one illumination source.

15. The combination of claim 14 wherein the low-adhesion adhesive coating is at least translucent.

16. The combination of claim 14 wherein the low-adhesion adhesive coating is capable of reversibly attaching to a base sheet cover.

17. The combination of claim 14 wherein the flap is hingedly attached to the base sheet and comes to rest upon the second side in the first closed position.

18. The combination of claim 14 wherein the flap is hemispherically-shaped with a slit bisecting the flap into flap halves.

19. The combination of claim 18 wherein the flap halves can be moved apart from one another to allow the cover to move to the second open position.

20. The combination of claim 18 wherein the flap is attached by its non-slit flap edges to the base sheet.
